(19) United States
(12) Patent Application Publication
(10) Pub. No.: US 2026/0074409 A1
(43) Pub. Date: Mar. 12, 2026

(54) MICROWAVE RESONATOR AND APPLICATIONS THEREOF

(71) Applicant: Technion Research & Development Foundation Limited, Haifa (IL)

(72) Inventor: Aharon BLANK, Haifa (IL)

(73) Assignee: Technion Research & Development Foundation Limited, Haifa (IL)

(21) Appl. No.: 19/325,593

(22) Filed: Sep. 11, 2025

Related U.S. Application Data
(60) Provisional application No. 63/693,210, filed on Sep. 11, 2024.

(51) Int. Cl. H01P 7/10; G01R 33/26; H01P 7/06

(52) U.S. Cl. CPC H01P 7/10; G01R 33/26; H01P 7/06

(57) ABSTRACT

A microwave resonator comprises a metallic structure formed with a cavity defining a symmetry axis, a pair of diamonds positioned at top and bottom ends of the cavity, and a layered dielectric structure between the diamonds. A microwave magnetic field is generated perpendicularly to the symmetry axis of the cavity in response to a static magnetic field and an excitation optical field, both directed parallel to the symmetry axis.

### RELATED APPLICATION(S)

This application claims the benefit of priority under 35 USC § 119(e) of U.S. Provisional Patent Application No. 63/693,210 filed on Sep. 11, 2024, the contents of which are all incorporated by reference as if fully set forth herein in their entirety.

### FIELD AND BACKGROUND OF THE INVENTION

The present invention, in some embodiments thereof, relates to an electromagnetic resonator and, more particularly, but not exclusively, to a microwave resonator and applications thereof.

Microwave frequency sources are used in many applications including radar systems, communications, navigation, precision metrology, and scientific instrumentation. An ideal frequency source would produce a pure sinusoidal signal that appears as a delta function in the frequency domain, as illustrated in FIGS. 1A and 1B, respectively. However, real-world frequency sources exhibit phase variations that cause spectral broadening around the carrier frequency, a phenomenon known as “phase noise.” The time-domain and frequency-domain of a signal exhibiting phase noise are illustrated in FIGS. 1C and 1D, respectively.

Phase noise is quantified as the amount of noise power in the spectral domain at a given frequency offset from the carrier frequency, expressed in decibels relative to the carrier power (dBc). For example, a phase noise specification of −100 dBc at 1 kHz offset for a 10 GHz source means that if the carrier power is P, then at frequencies 10 GHz±1 kHz, the noise power is 10⁻¹⁰×P. The phase noise performance typically decreases with the frequency.

Known microwave frequency sources include, crystal-controlled frequency sources, voltage-controlled frequency sources, and dielectric resonator frequency sources. An example type of crystal-controlled frequency source is a source comprising a sapphire cavity. Such sources can achieve phase noise levels better than −155 dBc at 1 kHz offset for 10 GHz sources.

A maser is a device that produces coherent electromagnetic waves at microwave or radio frequencies through the process of stimulated emission of radiation. The term maser is an acronym for Microwave Amplification by Stimulated Emission of Radiation. Unlike frequency sources that rely on electronic feedback circuits, masers operate on the principle of population inversion in atomic or molecular systems, where more particles occupy higher energy states than lower ones. The population inversion state is accompanied by oscillations that generate a microwave signal at the frequency corresponding to the energy level difference of the atomic or molecular systems. Solid-state masers can generate and amplify microwave radiation with very low additional thermal noise.

The active medium in solid-state masers typically includes paramagnetic species, mainly ions embedded in a crystal, such as ruby (Cr³⁺ in an Al₂O₃ crystal). The medium is excited into higher energy states using optical pumping, electrical pumping, or another microwave source. When the system relaxes, it emits microwave photons coherently, amplifying microwave signals.

Also known is a maser-based microwave amplifier which utilizes a diamond crystal with relatively broad spectral lines (about 10 MHz) situated inside a resonator with a relatively low-quality factor Q (about 200) [Sherman et al., 2022, Science Advances, Vol 8, Issue 49, DOI: 10.1126/sciadv.ade6527].

### SUMMARY OF THE INVENTION

According to some embodiments of the invention the present invention there is provided a microwave resonator for a microwave source system. The microwave resonator comprises a metallic structure formed with a cylindrical cavity defining a symmetry axis and having a top end and a bottom end, a pair of cylindrical diamonds positioned in the cavity at the top and bottom ends, and a layered dielectric structure between the diamonds. A microwave magnetic field is generated perpendicularly to the symmetry axis in response to a static magnetic field and an excitation optical field, both directed parallel to the symmetry axis.

According to some embodiments of the invention a diameter of the cavity and each of the cylindrical diamonds is at least 3 mm, e.g., from about 3 mm to about 9 mm, or from about 4 mm to about 8 mm, e.g., about 6 mm.

According to some embodiments of the invention the layered dielectric structure comprises a core layer made of a first dielectric between two layers made of a second dielectric.

According to some embodiments of the invention the first dielectric is a single crystal. According to some embodiments of the invention the first dielectric has permittivity of from about 2 to about 20. According to some embodiments of the invention the first dielectric having a dielectric loss characterized by a tan delta value of less than 0.001, the tan delta value being the ratio of a resistive current to a capacitive current within the first dielectric. According to some embodiments of the invention the first dielectric comprises Al₂O₃. According to some embodiments of the invention the first dielectric comprises intrinsic silicon. According to some embodiments of the invention the first dielectric comprises sapphire. According to some embodiments of the invention the first dielectric comprises a single crystal diamond.

According to some embodiments of the invention the second dielectric is a single crystal. According to some embodiments of the invention the second dielectric has permittivity of from about 10 to about 50. According to some embodiments of the invention the second dielectric having a dielectric loss characterized by a tan delta value of less than 0.002, the tan delta value being the ratio of a resistive current to a capacitive current within the second dielectric. According to some embodiments of the invention the first dielectric comprises the second dielectric is a perovskite. According to some embodiments of the invention the second dielectric comprises LaAlO₃. According to some embodiments of the invention the second dielectric comprises LiTaO₃.

According to some embodiments of the invention a permittivity of the first dielectric is less than a permittivity of the second dielectric. According to some embodiments of the invention a tan delta value of the first dielectric is less than a tan delta value of the second dielectric. According to some embodiments of the invention a permittivity of the first dielectric is less than a permittivity of the second dielectric, and a tan delta value of the first dielectric is less than a tan delta value of the second dielectric.

According to some embodiments of the invention the microwave resonator comprises an elongated dielectric insert, movable along a radial direction perpendicularly to the symmetry axis. According to some embodiments of the invention the insert is made of the first dielectric. According to some embodiments of the invention the insert is shaped as a rod.

According to some embodiments of the invention each of the diamonds has a [1 1 1] orientation. According to some embodiments of the invention each of the diamonds has paramagnetic defects. According to some embodiments of the invention the paramagnetic defects comprise negatively-charged nitrogen-vacancies (NV⁻). According to some embodiments of the invention a concentration of the NV⁻ is from about 1 ppm to about 20 ppm, more preferably from about 1 ppm to about 20 ppm, or from about 3 ppm to about 20 ppm or from about 1 ppm to about 10 ppm.

According to some embodiments of the invention the dimensions of the cavity and the diamonds are is selected such that a filling factor associated with the microwave magnetic field with respect to the diamond sample is at least 0.3, more preferably at least 0.7.

According to an aspect of some embodiments of the present invention there is provided a microwave source system. The system comprises the microwave resonator as delineated above and optionally and preferably as further detailed below.

According to some embodiments of the invention the microwave source system comprises a magnet having magnetic poles generating the static magnetic field, wherein a distance between the poles and the diamonds is less than 25 mm, e.g., from about 6 mm to about 20 mm.

According to some embodiments of the invention the microwave source system comprises light sources outside the cavity, wherein a distance between the light sources and the diamonds is less than 5 mm, e.g., from about 2 mm to about 3 mm.

According to an aspect of some embodiments of the present invention there is provided a microwave interferometry, which comprises the microwave source system as delineated above and optionally and preferably as further detailed below.

According to an aspect of some embodiments of the present invention there is provided a microwave radiometer, which comprises the microwave source system as delineated above and optionally and preferably as further detailed below.

According to an aspect of some embodiments of the present invention there is provided a navigation system, which comprises the microwave source system as delineated above and optionally and preferably as further detailed below.

According to an aspect of some embodiments of the present invention there is provided a communication system, which comprises the microwave source system as delineated above and optionally and preferably as further detailed below.

According to an aspect of some embodiments of the present invention there is provided a radar system, which comprises the microwave source system as delineated above and optionally and preferably as further detailed below.

According to an aspect of some embodiments of the present invention there is provided an imaging system, which comprises the microwave source system as delineated above and optionally and preferably as further detailed below.

According to an aspect of some embodiments of the present invention there is provided an ablation system, which comprises the microwave source system as delineated above and optionally and preferably as further detailed below.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

The patent or application file contains at least one drawing executed in color. Copies of this patent or patent application publication with color drawing(s) will be provided by the Office upon request and payment of the necessary fec.

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIGS. 1A-D are illustrations showing time-domain (FIGS. 1A and 1C) and frequency-domain (FIGS. 1B and 1D) of a pure sinusoidal signal (FIGS. 1A-B) and of a signal exhibiting phase noise (FIGS. 1C-D).

FIG. 2 is a schematic illustration of a microwave resonator for a microwave source system, according to some embodiments of the present invention.

FIG. 3 is a schematic illustration of a microwave source system according to some embodiments of the present invention.

FIGS. 4A-B are schematic illustrations explaining the concept of a maser that is based on nitrogen-vacancy (NV) centers. FIG. 4A illustrates an NV defect in the diamond crystal. FIG. 4B illustrates optical and magnetic energy levels of the NV. Optical irradiation allows pumping the magnetic levels to the spin |0

$$〉$$

state. Under a static magnetic field, the spin |−1

$$〉$$

state is lower in energy (e.g., about 10 GHz), and stimulated emission occurs.

FIG. 5 is a schematic illustration of an electromagnetic structure of a resonator and for NV-based maser, used in experiments performed according to some embodiments of the present invention. The top panel illustrates the structure of the resonator for frequency of about 14 GHz. The structure is based on a cylindrical hollow metallic structure with hole diameter of about 6 mm and with slits on top and bottom to allow efficient light access. In the metallic structure, there is a layered structure of two diamonds and, single crystals of LaAlO₃ and Al₂O₃, between the diamonds. The resonator also has an insert of Al₂O₃ for mechanical frequency tuning. The bottom panels show calculated magnetic (H) and electric (E) fields in the resonator, demonstrating large filling factor, as most of the magnetic energy is in the diamonds. The electric field is primarily inside the dielectric layers demonstrating a relatively high Q factor without metallic losses from the light entry surfaces.

FIG. 6 is a schematic illustration of a mechanical structure of the resonator of FIG. 5.

FIGS. 7A-B are schematic illustrations and an image of a maser device used in experiments performed according to some embodiments of the present invention. FIG. 7A is a schematic drawing of a custom-made maser resonator, featuring two ports for microwave (MW) input and output, and two optical windows for light irradiation from both sides. FIG. 7B is a photograph of the resonator in its open state. It is made of high purity aluminum, coated with silver. The central cavity has a diameter of 6 mm and holds a stack of two round diamonds (each 1 mm thick), with two LaAlO₃ single crystals (0.5 mm thick) and one Al₂O₃ single crystal (0.3 mm thick) placed between them (not shown in the photo, see FIG. 7D for details). There are two optical windows (slits in the metallic design) that allow two green LEDs (only one is shown) to efficiently illuminate the two diamonds from both sides.

FIGS. 7C-D show results of simulation performed for the maser device shown in FIGS. 7A-B. FIG. 7C shows simulation of the MW magnetic field distribution for the cavity's resonant mode, with the diamonds, LaAlO₃, and Al₂O₃ inside. The MW magnetic field is predominantly concentrated within the diamond crystals. FIG. 7D is the same as FIG. 7C, except for the MW electric field distribution, which is primarily concentrated within the LaAlO₃ and Al₂O₃ crystals. The static magnetic field (B₀) is perpendicular to the resonator surface and is along the metallic cylindrical cavity axis.

FIGS. 8A-D show microwave signal characteristics of the maser device shown in FIGS. 7A-B when placed inside an electromagnet. FIG. 8A shows spectrum analyzer trace of the maser MW signal acquired with a 6 MHz span, 1001 points, 2.33 ms sweep time, and 56 kHz resolution bandwidth, under 1.2 W optical excitation power from each LED. The horizontal black scale bar represents 1 MHz. FIG. 8B is the same as FIG. 8A except that data were acquired during periods of reduced magnetic field stability. FIG. 8C shows representative time-domain trace of the maser MW signal during a relatively stable period of the electromagnet. The inset shows corresponding spectral domain view of the same signal. FIG. 8D is the same as FIG. 8C, except that data were acquired during a period of reduced magnetic field stability.

FIGS. 9A-D show microwave signal characteristics of the maser device shown in FIGS. 7A-B when placed inside a superconducting magnet. FIG. 9A shows spectrum analyzer trace of the maser MW signal acquired with a 10 MHz span, 1001 points, 1.47 ms sweep time, and 91 kHz resolution bandwidth, under 1.2 W optical excitation for each LED. The horizontal black scale bar corresponds to 1 MHz. FIG. 9B shows spectrum analyzer data acquired using the “max hold” mode, showing accumulated frequency jitter of the maser MW signal over multiple scans. Acquisition parameters: 5 MHz span, 1001 points, 2.13 ms sweep time, and 47 kHz resolution bandwidth, under 1.2 W optical excitation for each LED. The horizontal black scale bar corresponds to 1 MHz. FIG. 9C shows representative time-domain trace of the maser signal during a period of relative field stability. The inset shows corresponding spectral domain representation of the same signal. FIG. 9D shows phase noise spectrum of the free-running maser, measured at low excitation power (about 440 mW) and following signal amplification using a low-noise amplifier.

FIG. 10 shows expected phase noise of diamond-based measure at about 77 K, compared to ruby-based maser at 1.5 K. Shown are nominal calculated situation with T_{sys}=4.5 K, Pᵢₙ=0.1 μW, Q=2×10⁶, f₀=14.5 GHz, f_{c}=300 Hz (curve (a)); ultimate calculated results for T_{sys}=3.1 K, Pᵢₙ=1 μW, Q=1×10⁸, f₀=14.5 GHz, f_{c}=300 Hz (curve (b)); and calculated results for ruby maser, based on parameters of the system described in [Dick et al., IEEE Transactions on Instrumentation and Measurement 40, 174 (1991)], with T_{sys}=10 K, Pᵢₙ=10⁻¹¹ W, Q=1×10⁹, f₀=2.6 GHz, f_{c}=300 Hz (curve (c)).

FIG. 11 is a schematic illustration of a two-port configuration with a high-Q sapphire resonator, corresponding to curve (a) of FIG. 10. The maser output is coupled into the sapphire resonator, forming a feedback loop that stabilizes the oscillation frequency stability and reduces phase noise.

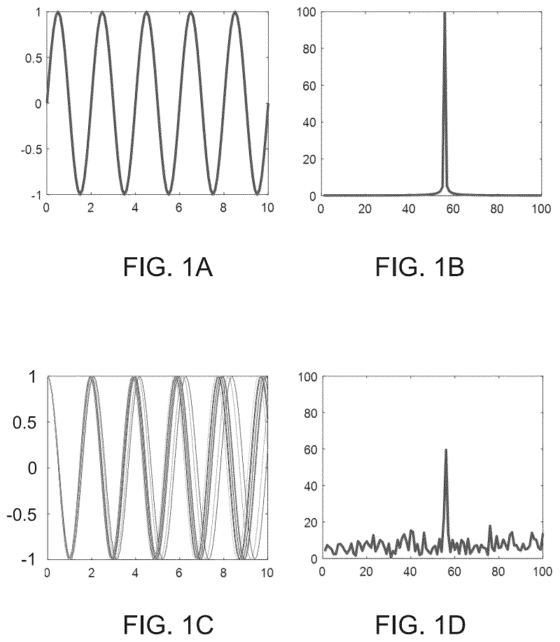

### DESCRIPTION OF SPECIFIC EMBODIMENTS OF THE INVENTION

The present invention, in some embodiments thereof, relates to an electromagnetic resonator and, more particularly, but not exclusively, to a microwave resonator and applications thereof.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

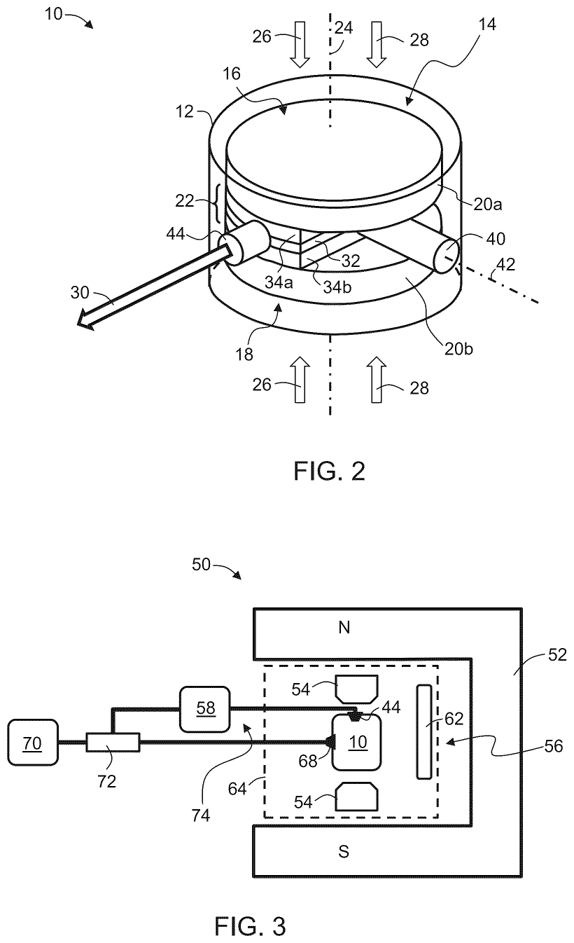

Referring now to the drawings, FIG. 2 is a schematic illustration of a microwave resonator 10 for a microwave source system, according to some embodiments of the present invention. Microwave resonator 10 comprises a metallic structure 12 formed with a cavity 14 defining a symmetry axis 24 and having a top end 16 and a bottom end 18. Metallic structure 12 provides electromagnetic shielding and defines the resonant characteristics of cavity 14. Metallic structure 12 is preferably formed from copper. Alternative metals for metallic structure 12 include, without limitation, silver, aluminum, brass, bronze, stainless steel, gold-plated copper or silver, niobium.

Cavity 12 is preferably cylindrical. The cylindrical geometry is particularly advantageous for achieving uniform field distributions and high quality factors. A pair of diamond structures 20a, 20b are positioned in cavity 14 at top end 16 and bottom end 18. Diamond structures 20a, 20b serve as the active medium for microwave generation through stimulated emission. The shape of structures 20a and 20b is optionally and preferably the same as the shape of cavity 14. For example, when cavity 14 is cylindrical, diamond structures 20a and 20b are also cylindrical. Alternatively, structures 20a and 20b can have a shape that is different from the shape of cavity 14. For example, cavity 14 can be cylindrical and diamond structures 20a and 20b can be non-cylindrical. In preferred embodiments, the diameter of both the cavity and each of the cylindrical diamonds is at least 3 mm, which provides sufficient volume for achieving adequate microwave power output while maintaining reasonable filling factors.

A layered dielectric structure 22 is positioned between diamonds 20a and 20b. Structure 22 provides mechanical support for diamonds 20a and 20b, and also contributes to distribution of electromagnetic field within cavity 14. Structure 22 can also be used to tune the resonant frequency of the resonator 10. In some embodiments of the present invention, layered dielectric structure 22 comprises a core layer 32 made of a first dielectric material positioned between two layers 34a, 34b made of a second dielectric material. This configuration can enhance the coupling between the diamond active medium and the cavity modes. In some embodiments of the present invention Cavity 14 is preferably characterized by unloaded quality factor Q of more than 500 and no more than 5000, e.g., about 2000.

In relation to a maser cavity, “quality factor,” also abbreviated as “Q factor,” refers to a dimensionless parameter that characterizes the resonant performance of the cavity, defined as the ratio of the total electromagnetic energy stored within the cavity to the energy dissipated per oscillation cycle, multiplied by 2π.

As used herein, “unloaded quality factor,” in relation to a maser cavity, refers to the ratio of the total electromagnetic energy stored within the cavity to the energy dissipated per oscillation cycle due solely to internal loss mechanisms, multiplied by 2π. Internal loss mechanisms may include, for example, ohmic losses in cavity walls, dielectric absorption, and radiation leakage. The unloaded Q factor thus represents an intrinsic characteristic of the cavity, characterizing the energy retention capability of the cavity independent of external circuitry and any external coupling to input or output ports. The unloaded Q factor is distinguished from a loaded quality factor that includes additional losses attributable to external coupling. Maser cavity having a higher Q factor or higher unloaded Q factor exhibits lower energy loss and narrower resonance linewidth, and vice versa.

In response to a static magnetic field 26 and an excitation optical field 28 directed parallel to symmetry axis 24, a microwave magnetic field 30 is generated perpendicularly to symmetry axis 24. Resonator 10 may comprise an output port 44 configured to output microwave magnetic field 30. Port 44 is optionally and preferably connectable to a coaxial cable or any other device suitable for guiding microwave radiation to an appliance system 70 (not shown, see FIG. 3). Optionally, resonator 10 may also comprise a microwave input port 68 (not shown, see FIG. 3) configured to receive a microwave feedback signal from an external resonator 58 (not shown, see FIG. 3), as further detailed hereinbelow.

Magnetic field 26 can be generated by a permanent magnet (not shown, see FIG. 3) positioned above top end 16 and below bottom end 18 of cavity 14. Optical field 28 can be generated by an optical source (not shown, see FIG. 3) equipped with optics for directing field 28 onto top end 16 and/or bottom end 18 of cavity 14.

The dimensions of cavity 14 and diamonds 20a, 20b are preferably selected such that the filling factor associated with the microwave magnetic field is at least 0.7. The filling factor represents the fraction of the electromagnetic energy that is stored in the active medium (diamonds) compared to the total energy stored in the resonator. A high filling factor (>0.7) ensures efficient coupling between the active medium and the electromagnetic field, leading to higher gain and better overall performance.

The dielectric material forming core 32 optionally and preferably comprises a single crystal. Representative examples of single crystal materials suitable for core layer 32 include, without limitation, Al₂O₃ (sapphire), yttrium aluminum garnet (YAG), magnesium oxide (MgO), silicon carbide (SiC), quartz (SiO₂), titanium dioxide (TiO₂), and zinc oxide (ZnO). Also contemplated are ceramic materials including, without limitation, aluminum nitride (AlN), beryllium oxide (BeO), and silicon nitride (Si₃N₄). The dielectric material forming layers 34a, and 34b can be a perovskite, also in single crystal form. Representative examples of materials suitable for layers 34a and 34b include, without limitation, LaAlO₃ (lanthanum aluminum oxide), strontium titanate (SrTiO₃), barium strontium titanate (Ba₁₋ₓSrₓTiO₃), lanthanum titanate (La_{2/3}TiO₃), neodymium gallate (NdGaO₃), and potassium tantalate (KTaO₃). Also contemplated are non-perovskite materials such as, but not limited to, yttrium iron garnet (YIG), gadolinium gallium garnet (GGG), calcium fluoride (CaF₂), barium titanate (BaTiO₃), and lead zirconate titanate (PZT). The material forming core 32 is preferably different than the material forming layers 34a and 34b. In some embodiments of the present invention material forming core 32 comprises Al₂O₃ and the material forming layers 34a and 34b. comprises LaAlO₃.

In some embodiments of the present invention, microwave resonator 10 comprises an elongated dielectric insert 40 that is movable along a radial direction 42 perpendicular to the symmetry axis 24. Insert 40 is illustrated as a rod but can have other shapes as desired. Insert 40 provides a mechanism for tuning the resonant frequency of cavity 14. In some embodiments of the present invention insert 40 is made of the same material as core 32 (e.g., Al₂O₃) to maintain consistency in the electromagnetic properties. By adjusting the position of the insert radially within cavity 14, the effective dielectric constant and thus the resonant frequency can be continuously varied.

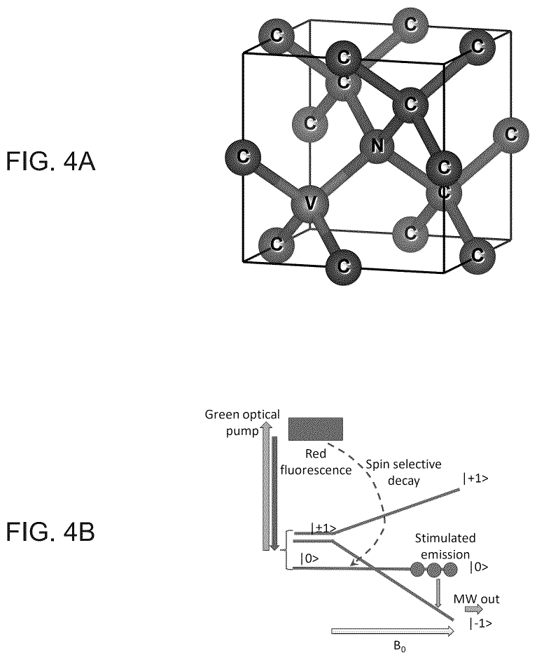

Diamonds 20a and 20b preferably contain paramagnetic defects, such as, but not limited to, nitrogen impurities that form nitrogen-vacancy (NV) centers (not shown, see FIG. 4A). The NV centers serves as the active species responsible for microwave generation. The concentration of nitrogen impurities is preferably from about 3 ppm to about 40 ppm, e.g., about 20 ppm. This concentration range provides sufficient density of active centers for adequate gain while avoiding excessive broadening of the spectral lines that would occur at higher concentrations. Diamonds 20a and 20b preferably have a [1 1 1] crystallographic orientation. This embodiment is particularly useful when the diamonds contain paramagnetic defects, such as nitrogen-vacancy centers, because it allows alignment of the nitrogen-vacancy centers with respect to the applied magnetic field. This orientation enhances the population inversion and stimulated emission efficiency.

The NV centers in the diamonds exhibit a spectral linewidth of from about 5 MHz to about 10 MHz, e.g., about 6.4 MHz. Such linewidth is sufficiently narrow to provide coherent emission and yet sufficiently broad to allow for practical excitation schemes. The specific electronic structure of NV centers allows static magnetic field 26 to split the energy levels of the NV centers through the Zeeman effect, creating an energy level structure for population inversion. The optical excitation field 28 which in some embodiments of the present invention is visible light provides the pumping mechanism to create and maintain the population inversion. For example, optical field 28 at wavelength of from about 500 to about 600 nm, e.g., about 532 nm can be used for optical excitation. The produced microwave field 30 at zero magnetic field can be at a frequency of from about 2.5 to about 3 GHz, e.g., about 2.87 GHz. With the application of static magnetic field 26, the produced microwave field 30 can be at a frequency of from about 1 GHz to about 40 GHz.

Reference is now made to FIG. 3, which is a schematic illustration of a microwave source system 50 according to some embodiments of the present invention. Microwave source system 50 comprises a microwave resonator, which can be, for example, microwave resonator 10 described above with respect to FIG. 2. System 50 also comprises a magnet 52 having magnetic poles (two poles, N, S are illustrated) that generate the static magnetic field 26 (see FIG. 2). The distance between the magnetic poles and the diamonds in resonator 10 is optionally and preferably less than 25 mm, so as to ensure sufficiently uniform magnetic field coupling while maintaining a compact system design. Magnet 52 can, in some embodiments of the present invention be a superconducting magnet in persistent mode. The advantage of these embodiments is that the magnetic field fluctuations are reduced.

System 50 can also comprise one or more light sources 54 positioned outside the cavity of resonator 10 for emitting optical field 28 (see FIG. 2) to excite the diamonds to produce the microwave field. In some embodiments of the present invention light sources 54 are configured to irradiate both the top end and the bottom end of the cavity of resonator 10. The distance between light source(s) 54 and the diamonds in resonator 10 is optionally and preferably less than 5 mm, so as to improve the optical coupling and excitation. In some embodiments of the present invention light source(s) 54 provide optical excitation power of at least 0.1 or at least 0.2 or at least 0.4 or at least 0.8 or at least 1 W per source. In preferred embodiments, the light sources comprise green LEDs providing wavelength of from about 500 nm to about 600 nm, e.g., about 532 nm.

Preferably, microwave source system 50 is designed to operate at cryogenic temperatures, for example, in the range of from about 50K to about 200K. Operation at these moderate cryogenic temperatures is advantageous since it increases the population difference between energy levels, reduces thermal noise, and improves the coherence properties of the NV centers. The Inventor found that system 50 can generate continuous-wave microwave output power of at least −30 dBm at these cryogenic temperatures, which is sufficient for many applications while demonstrating clear maser action. Thus, in some embodiments of the present invention microwave source system 50 comprises a cryogenic cooling system generally shown at 56 configured to maintain resonator 10 at the aforementioned cryogenic temperatures. Cooling system 56 can comprise a cooling device 62 and a vacuum chamber 64, where at least the cavity 14 of resonator 10 is placed in the vacuum chamber 64. In some embodiments of the present invention light sources 54 is/are placed in the vacuum chamber 64, and in some embodiments of the present invention light sources 54 is/are placed outside vacuum chamber 64. Similarly, in some embodiments of the present invention magnet 52 is placed in vacuum chamber 64, and in some embodiments of the present invention magnet 52 is placed outside vacuum chamber 64. Representative examples of cryogenic cooling system suitable for the present embodiments including, without limitation, a Stirling cooler, a liquid nitrogen cooler, and a liquid helium cooler. In preferred embodiments, the cryogenic cooling system is a helium-free Stirling cooler, which provides the advantage of not requiring consumable cryogens. This makes the system more practical for field deployment and reduces operating costs.

Microwave source system 50 can generate microwave field at any microwave frequency, depending, e.g., on the strength of static magnetic field 26. In experiments performed by the inventor using a magnetic field having magnetic flux density of about 0.62 T, a microwave frequency of about 14.5 GHz was demonstrated. The inventor found that the frequency of the produced microwave field 26 increases approximately linearly (e.g., with deviation of about 10% from linearity) with the magnetic flux density of field 30. To reduce frequency jitter, the power of light sources 54 is optionally and preferably no more than 10 times the maser threshold.

As use herein “maser threshold” is defined as the excitation power at which the net power gain due to population inversion equals the resonator losses, quantitatively expressed as Qₜₕ=Qₘ, where Qₜₕ is the minimum quality factor required to sustain maser self-oscillating action and Qₘ is the quality factor contribution from the maser's gain medium. At the threshold, oscillation can just be sustained with minimal optical pumping power.

In some embodiments of the present invention system 50 also comprises an external resonator 58 coupled to microwave resonator 10. The external resonator 58 preferably has a quality factor of at least 105 or at least 5×10⁶ or at least 10⁶ and it preferably comprises sapphire. In these embodiments, microwave field 30 (shown FIG. 2) that is outputted from resonator 10 is coupled, for example, by means of a directional coupler 72, into the external resonator 58, to form a feedback loop 74 between the two resonators 10, 58. The advantage of these embodiments is that feedback loop 74 improves the frequency stability and reduces the phase noise. Microwave lines in FIG. 3 are illustrated as thick lines, connecting resonator 10, resonator 58 and appliance system 70. Specifically, the microwave output from resonator 10 is transmitted to an input terminal I of directional coupler 72, which transmits a portion (e.g., from about 10 to about 30 dB) of the microwave power via a coupling port C and another portion of the microwave power via an output terminal. Coupling port C of directional coupler 72 connects to resonator 58, and output terminal O of directional coupler 72 connects to appliance system 70. The output from resonator 58 is transmitted as a feedback to the input port 44 of resonator 10.

Microwave source system 50 can be integrated with various types of appliance systems 70. For scientific applications, it can be integrated with electron spin resonance (ESR) spectrometry equipment for signal analysis. Other types of systems in which microwave source system 50 can be used including, without limitation, microwave interferometry systems, navigation systems, communication systems, radar systems, imaging systems, ablation systems, microwave radiometry systems, and the like. Microwave source system 50 can also be configured as a microwave oscillator system, operating as a free-running maser oscillator. In this configuration, the system provides continuous oscillation at its natural frequency determined by the NV center transitions and the applied magnetic field, without requiring an external driving signal.

As used herein the term “about” refers to ±10%.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

Microwave sources including sapphire oscillators (SO) have a relatively low phase noise for the frequency range of about 10 GHz, reaching better than-155 dBc for 10 GHz source at 1 kHz frequency offset from carrier [IEEE Transactions on Ultrasonics, Ferroelectrics, and Frequency Control, vol. 56, no. 2, February 2009 263]. The inventor realized that known sapphire oscillators are, however, relatively large and bulky (usually placed inside a rack mount package and weighs a few kgs), and also very expensive. The inventor also realized that known sapphire oscillators suffer from limited short time frequency tunability.

Some embodiments of the invention relate to a microwave source that employs maser technology. Gas-based masers, akin to the microwave equivalent of lasers, such as the hydrogen gas maser, are renowned for their frequency stability and are employed as frequency references [James P. Gordon, “THE MASER”, Scientific American, Vol. 199, No. 6 (December 1958), pp. 42-51]. Gas-based masers have fixed frequency due to the specific internal energy levels of the gas. Further, their power output, which about 60-100 dBm is (see, e.g., typically www(dot)ivscc(dot)gsfc(dot)nasa(dot)gov/meetings/tow2013/Diegel(dot)MW(dot)pdf) is insufficient for use as practical low-phase noise microwave sources. For example, at room temperature, the thermal is about −177 dbm/Hz (see, e.g., www(dot)microwavejournal(dot)com/articles/39932-the-importance-of-crystal-oscillators-with-low-phase-noise. Therefore, in order to achieve, e.g., phase noise of −160 dBc at some frequency offset from the carrier (say, about 1 kHz), the corresponding microwave source requires a power output of at least −17 dBm so as to dominate the thermal noise.

Known in the art are solid-state masers such as the Ruby-maser, which emit greater microwave power than gas based masers [Kikuchi, Chihiro; Lambe, John; Makhov, George; Terhune, Robert W. (1959). “Ruby as a Maser Material.” Journal of Applied Physics 30 (7): 1061-1067]. However, these masers require operation at cryogenic temperatures (approximately 1 K), presenting significant challenges for practical application.

In recent years, there has been considerable effort directed toward developing solid-state maser sources that can operate at room temperature [Nature volume 555, pages 493-496, 2018]. These designs are based on unique quantum system of color centers (defects) in diamond single crystal, described in FIGS. 4A-B.

The Inventor realized that conventional designs of NV⁻ based masers have only achieved a modest output power of approximately 1 pW [Zollitsch et al., Communications Physics volume 6, 295 (2023)], and their phase noise characteristics have not been thoroughly assessed.

In a design of a microwave source employing a maser technology it is desirable to ensure that the microwave losses (e.g., cavity losses, outcoupling losses) be smaller than the net gain by the stimulated emission effect, allowing the cavity to sustain maser self-oscillating action. The quality factor of the cavity holding the masing material beyond which the net gain is above the losses is referred to herein as a “maser threshold,” and is denoted Qₜₕ. The maser threshold can be quantitatively written as:

$${Q}_{th} = {Q}_{m} ≡ \frac{1}{{ηχ}^{″}} = \frac{8}{ηΔ {nμ}_{0} {γ}^{2} ℏ {T}_{2}^{*}} , \qquad [ 1 ]$$

where Qₘ is the quality factor due to the maser's gain medium, in absolute value (but actually having a negative value), χ″ is the microwave magnetic susceptibility of the NVs in the diamond at resonance, and η is filling factor defined as

$$η = {\int }_{diamond} {\vert {B}_{1}^{t} \vert}^{2} / {\int }_{resonator} {\vert {B}_{1} \vert}^{2}$$

where the nominator involves the size of the MW magnetic field component,

$${B}_{1}^{t} ,$$

tangential to the direction of the static magnetic field, B₀, and the denominator includes the size of the total MW magnetic field B₁. μ₀ and γ are, respectively, the free space permeability and electron gyromagnetic ratio factor, and T₂* is related to the inverse spectral linewidth of the NV⁻, Δf, by the expression T₂*=1/πΔf, and Δn is the population inversion difference between the upper and lower energy levels of the NV⁻ transition used for maser amplification, per unit of volume.

The controllable parameters in EQ. 1 include: (i) the quality factor of the resonator, Q, (ii) the filling factor of the sample in the resonator, η, and (iii) the concentration of the NVs in the diamond (manifested through Δn), which also determines, at least partially, the value of T₂*. For diamonds that are not ¹²C enriched, with about 1 ppm or less N impurities in the diamond, T₂* typically does not exceed 0.8 μs. The concentration of NVs achievable in the diamond is proportional to the concentration of N, typically reaching 30-50% of it. For higher N concentrations, T₂* starts to drop, for example, reaching about 0.45 μs in 10 ppm N and about 40 ns for about 100 ppm of N [van Wyk et al. (1997). J. Phys. D: Appl. Phys. 30, 1790].

Conventionally, diamond-based masers include diamonds having cube or rhombic geometry and a [1 0 0] cut. These diamonds have N concentration of from about 1 ppm to about 10 ppm, which, following transformation of N substitutional to NV⁻, result in NV⁻, concentration of from about 0.1 ppm to about 4 ppm. The diamonds are placed in the center of resonators with high Q and low η. Typically, in these resonators η is about 0.02, and so Q is as high as possible, e.g., larger than 20,000 or even larger than 25,000, to compensate for the low value of η. The Inventor found that microwave sources employing diamond in the center of resonators with high Q, and low η have several drawbacks, as will now be explained. Firstly, the high Q limits the range of tunability of the frequency of the device. For example, at 10 GHz, Q of 20,000 limits the frequency range to 0.5 MHz. Secondly, the [1 0 0] cut necessitates placing the diamond in tilt positions with respect to the resonator. This is because in conventional designs the static magnetic field is along the NV⁻ axis, which is about 57° off the [1 0 0] crystallographic plane of the diamond, and the static magnetic field is perpendicular to the cavity faces (see for example, www(dot)nature(dot)com/articles/s42005-023-01418-3). Such a tilt, however, is hard to align. Thirdly, the light excitation scheme is inefficient. Fourthly the lack of good physical contact between the diamond and the rest of the resonator parts, and the fact that the resonator itself, due to its very high Q, needs to be far away from the metallic enclosure of the device leads to very poor heat management that limits the output power of the device [Communications Physics volume 6: 295 (2023)]. Fifthly, the requirement for large Q also leads to a large shield that has to be far away from the dielectric structure resonator, and this makes it difficult to place the resonator inside compact and homogenous static magnet.

The Inventor found that the maser device is energetically non-efficient in converting optical pumping power to microwave power. Note that ideally, namely when every green light photon result in one microwave photon, the energy efficiency is only 2×10⁻⁵ because the frequency of green light is about 5×10¹⁴ Hz, and the frequency of microwave radiation is about 10¹⁰ Hz. Thus, the required pump optical power should be 1/(2×10⁻⁵)=50,000 higher than the desired microwave power output. For example, for a power output of −14 dBm (about 0.5×10⁻⁴ W), the required optical input power is about 50,000×0.5×10⁻⁴=2.5 W. Such optical power is not feasible in conventional designs due to lack of heat dissipation.

The present Example describes microwave source having a relatively long T₂*, e.g., at least 200 ns, for example, from about 200 ns to about 2000 ns or from about 200 ns to about 1000 ns, providing a relatively narrow emission line (Δf˜1/πT₂*). The N concentration is from about 1 ppm to about 20 ppm, more preferably from about 1 ppm to about 20 ppm, or from about 3 ppm to about 20 ppm or from about 1 ppm to about 10 ppm, with corresponding NV⁻ concentration of from about 0.3 ppm to about 8 ppm. While it is recognized that the value of T₂* drops for N concentrations above 1 ppm, the Inventor utilizes N concentrations that are more than 1 ppm or more than 2 ppm or even at least 3 ppm, e.g., from about 5 ppm to about 20 ppm or from about 10 ppm to about 20 ppm. This is because the drop in the value of T₂* is mild for N concentrations from about 1 ppm to about 10 ppm (www(dot)iopscience(dot)iop(dot)org/article/10(dot)1088/0022-3727/30/12/016).

Use of higher N concentration is advantageous as it allows having larger NV⁻ concentration, and thus achieving more easily the maser threshold with minor increase in the spectral line of the NVs. This allows fabrication of a microwave source with paratactically achievably static field homogeneity without presenting a significant compromise on the size of the cavity.

While traditionally one would be tempted to use only diamonds with very long T₂* with N concentration of less than 1 ppm in order to archive and a very narrow spectral line (according to Gordon et al., Physical Review 99, 1264 (1955), the actual 3 dB linewidth of the emitted maser signal is narrower than Δf˜1/πT₂*), the Inventor realized that such this would require very homogenous magnetic field, which is difficult to achieve. The Inventor found that it is advantageous in the overall design consideration to use N concentration higher than 1 ppm, and correspondingly larger NV− concentration.

The microwave source of the present embodiments preferably comprises ¹²C enriched diamonds that are fabricated by chemical vapor deposition (CVD). The CVD technique is advantageous over high pressure-high temperature (HPHT) techniques because it allows better control over the diamond composition, and can be applied to isotopically pure ¹²C material, improving the achievable value of T₂*. Yet, use of HPHT techniques is also contemplated, as some of these techniques produce diamonds with the above concentration of substitutional N impurities.

The microwave source of the present embodiments preferably provides microwave power output of at least −17 dBm at room temperature, or at least −36 dBm at cryogenic or liquid helium temperatures (e.g., about 4K). Such an output is useful because it corresponds to a low phase noise level, e.g., −160 dBc or less for frequencies that are from about 1 kHz to about 10 kHz away from the carrier that is below the unavoidable thermal noise level.

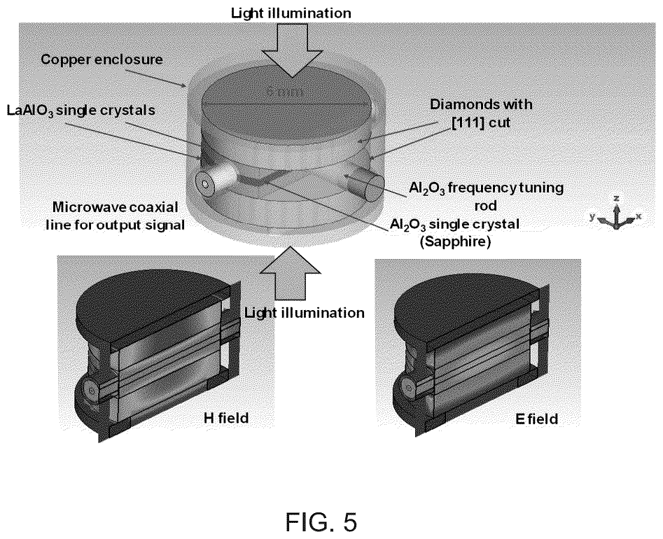

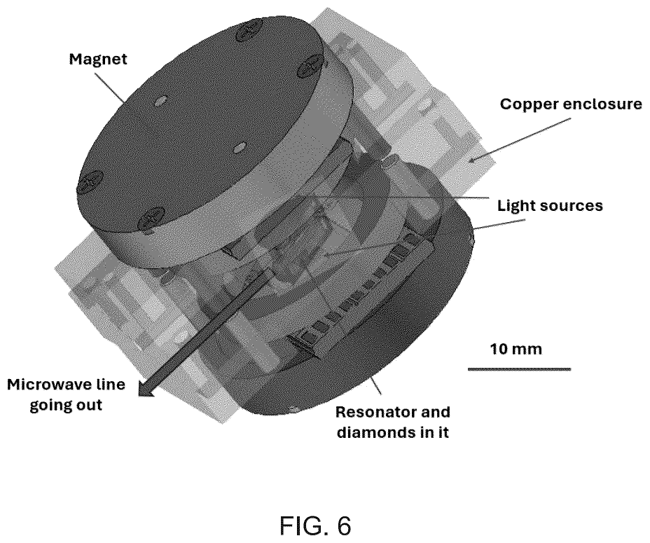

A schematic illustration of a resonator for a microwave source according to some embodiments of the present invention is shown in FIG. 5, and a schematic illustration of a microwave source including the resonator is illustrated in FIG. 6.

The top panel of FIG. 5 illustrates a structure of the resonator, which is suitable for output radiation of about 14 GHz. Output radiation at other frequencies can be achieved by selecting at least one of the dimensions for the resonator (larger for lower frequencies in a linear faction), the permittivity of the crystals, and their relative compositions.

The exemplified resonator comprises a metallic structure formed with a cylindrical cavity having a diameter of at least 3 mm, e.g., from about 3 mm to about 9 mm, or from about 4 mm to about 8 mm, e.g., about 6 mm. Preferably, the metallic structure comprises copper. A layered structure is placed between two diamond layers, preferably single crystal diamonds, within the cylindrically cavity. The diamond layers and layers of the structure are perpendicular to the symmetry axis of the cylinder. The layered structure comprises a core layer of Al₂O₃, between two LaAlO₃ layers. The core layer is in contact with the two LaAlO₃ layers, and the LaAlO₃ layers are in contact with the two diamond layers. The diamond layers are preferably cylindrical, having generally flat surfaces perpendicular to the symmetry axis of the cylindrical cavity, and curved walls that are generally parallel to the curved wall of the cavity. The height of each diamond is at least 0.5 mm, e.g., from about 0.5 to about 1.5 mm, and the diameter of each diamond is approximately the same as the inner diameter of the cylindrical cavity (e.g., about 6 mm), allowing a physical contact between the diamonds and the metallic structure. Preferably, the diamonds are cut along the [1 1 1] crystallographic direction. The resonator optionally and preferably also comprises an insert of Al₂O₃. The insert is movable radially with respect to the symmetry axis of the cylinder, for mechanical frequency tuning.

The pump light is at a frequency selected to induce inversion of spin energy levels of the diamond. Typically, the pump light is green light. The pump light is generated by light sources, such as, but not limited to, LEDs, coupled to the metallic structure (see, FIG. 6) at the top and the bottom surfaces of the cylindrical cavity. Light enters the cavity through slits, preferably 0.5-1 mm in width of gap-metal-gap, at the top and the bottom surfaces of the cylindrical cavity. Preferably, the distance between the output surface of the light sources and the outer surfaces of the diamonds that face the light sources is less than 5 mm, e.g., from about 2 mm to about 3 mm.

The resonator is placed in a static magnetic field, which is generated by a magnet, which is preferably, but not necessarily, a permanent magnet. The distance between the poles of the magnet and the flat surfaces of the diamonds is preferably less than 25 mm, e.g., from about 6 mm to about 20 mm. The direction of the static magnetic field is along the symmetry axis of the cylindrical cavity and the direction of the microwave magnetic field is perpendicular to the symmetry axis of the cylindrical cavity. Preferably, the microwave output is guided by a coaxial line coupled to the core layer and inner encapsulation layers (FIG. 5).

This resonator of the present embodiments provides a relatively high filling factor η of more than 0.7 for the two diamonds together. This means that more than 70% of the microwave magnetic energy in the resonator is in the diamonds, a significant improvement compared to conventional designs that rely on the use of dielectric resonator with diamond placed in it, where the typical filling factor about 2%. The high filling factor of the present embodiments allows achieving maser oscillation conditions with a smaller value of Q, typically no more than 5000, e.g., about 2000. The advantage of the microwave source of the present embodiments is that it provides capability to tune the frequency electronically (which is very fast, compared to mechanical tuning) within the frequency bandwidth of the resonator and also obtain much higher output power, resulting in low phase noise as explained above. Calculations of the magnetic (H) and electric (E) fields in the resonator are shown in the bottom panel of FIG. 5. As shown, most of the magnetic energy is in the diamonds, meaning the filling factor is large, and the electric field is primarily inside the dielectric layers in the center, meaning that Q is sufficient to pass the maser threshold and enable oscillations without metallic losses from the light entry surfaces.

The microwave source of the present embodiments is advantageous because it has a modest Q allowing fast tuning range of from about 5 MHz to about 10 MHz by changing the static field applied on the diamonds, all inside the bandwidth of the resonator. The microwave source of the present embodiments is also advantageous because the diamond are cut along the direction, allowing easy placement of the diamonds in the metallic structure, while aligning the direction with the external static field. The microwave source of the present embodiments is also advantageous because the light excitation is through a wall that is very close to the diamond, allowing the use of high power green LEDs. The microwave source of the present embodiments is also advantageous because the physical contact between the diamonds and the metallic structure improves the heat dissipation, facilitating high microwave output of the maser device. The microwave source of the present embodiments is also advantageous because it provides a small confined structure (about 10 mm in width, namely five times smaller than conventional diamond based microwave sources), allowing use of a compact static magnetic field source close to the diamonds.

### Example 2

In this Example, a continuous-wave diamond-based maser oscillator operating at about 14.5 GHz and moderate cryogenic temperatures (about 180 K), and achieving output power levels exceeding −30 dBm (1 μW) is described. This oscillator represents a two-orders-of-magnitude improvement over conventional diamond or ruby-based maser oscillators. The oscillator integrates a high-Q (about 2460) compact metallic microwave cavity with optically pumped [1 1 1]-oriented NV-rich diamond crystals. The cavity supports light coupling and thermal dissipation, allowing sustained optical excitation at power levels of more than 1 W using cost-effective green LEDs. Stable maser operation with good spectral quality is demonstrated and its output is validated through both frequency- and time-domain analysis with phase noise data when operated in “free running” mode. Phase noise estimations based on Leeson's model are also provided and it is shown that, when coupled to a high-Q external resonator, such masers approach thermally limited phase noise levels.

### INTRODUCTION

Various energy pumping schemes have been suggested to achieve a state of population inversion in solid-state masers, where more electrons occupy a higher energy level than a lower one. The population inversion state is accompanied by oscillations that generate a microwave signal at the frequency corresponding to the energy level difference. The emission of additional microwave radiation can also be stimulated by incoming microwave radiation, thus amplifying the incoming signals. The Inventor found that conventional solid-state masers suffer from low power output in continuous wave mode of operation. For example, when used as an oscillator, the best performance to date of diamond-based masers has shown an output power of only −54.1 dBm (3.9×10⁻⁹ W) [Zollitsch et al., supra]. Ruby-based maser oscillators at temperatures of 1.5 K have power levels on the range of at most 10⁻⁹ W [Wang et al., JPL-NASA progress report 42-107 (1991)]. The Inventor realized that such power levels are too low for masers to serve as practical oscillators in applications requiring ultra-low phase noise, and that they restrict their use as amplifiers due to low saturation input power. Power levels achievable by conventional solid state masers are too low since the thermal noise at room temperature is approximately −177 dBm/Hz, and so a phase noise level of, say, −160 dBc, an output power of at least −17 dBm to is required so as to remain dominant above the thermal noise. At lower temperatures, the thermal noise limit is reduced, but the Inventor realized that a significant reduction requires deep cryogenic temperatures, which greatly complicates the oscillator system.

The Inventor have devised a diamond-based solid-state maser operating at approximately 14.5 GHz, with a continuous-wave output power of up to −30 dBm (1 μW) at modest cryogenic temperatures of 180 K. The solid-state maser described in this example employs a metallic microwave resonator with a relatively high-quality (Q) factor, allowing light access while ensuring efficient coupling. The described solid-state maser can operate in conjunction with relatively large and unconventional diamond samples, allowing better thermal dissipation. The microwave output power levels achieved by the maser of the present embodiments exceed those of conventional masers by more than two orders of magnitude.

### An NV-Based Maser Device

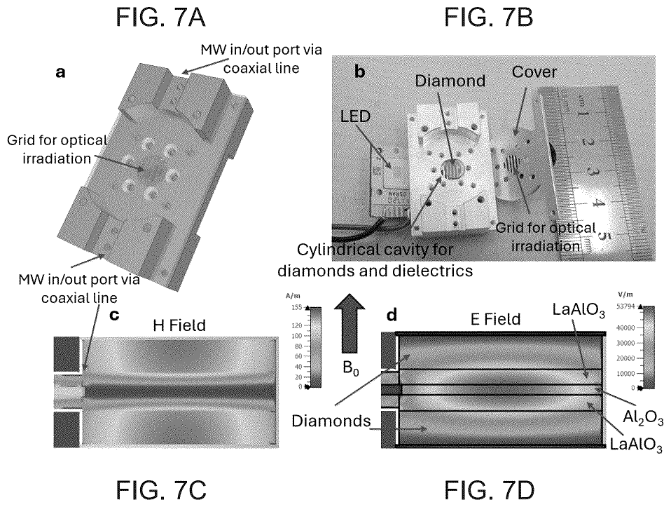

FIGS. 7A-B present the maser device design. The design is based on a unique microwave resonator that incorporates both metallic and dielectric components, facilitating high-efficiency optical pumping schemes. The maser device exceeds the maser threshold, wherein the net power gain due to population inversion is greater than the resonator losses (see EQ. 1 in Example 1). A possible approach to exceed the maser threshold is to use resonators with Q above 20,000. However, the Inventor realized that maintaining such high Q values often requires limiting the diamond size and NV concentration to reduce overall resonator losses. This is because dielectric losses increase with higher nitrogen (and thus NV) concentrations. Limiting the NV concentration and diamond volume, in turn, results in lower values of both η and Δn. Additionally, such high-Q designs often suffer from poor thermal management, as the dielectric structures are kept away from metallic walls to minimize microwave losses. Unlike conventional solid-state masers, the maser of the present embodiments benefits from proximity to the metallic walls, which aids in dissipating the heat generated by optical pumping. An additional advantage of the maser described herein is that it employs diamonds with high NV concentration (about 20 ppm), ensuring sufficient population inversion during emission. A further advantage of the maser described herein is that it supports optical excitation power of about 1 W, which is significantly high compared to conventional solid-state masers than. Ideally, one green-light photon would produce one microwave photon, meaning that only about 2.5×10⁻⁵ (equal the ratio of frequencies ˜14.5×10⁹/5.6×10¹⁴) of the optical energy can be converted into a microwave signal. Consequently, with 1 W of optical excitation power, accounting for losses and mismatches, the expected output power can be at least 1 μW, assuming a sufficient number of NV centers in the structure.

The maser device shown in FIGS. 7A-B comprises a metallic cavity with unloaded Q of about 2460 into which a stack of two large diamonds and dielectric materials are tightly placed. The diamonds and dielectric materials relatively small effects of the unloaded Q factor. Optical windows that are placed in a way that has negligible on the unloaded Q factor while allowing efficient light excitation of the diamonds by simple and affordable green LEDs. The tight structure provides an efficient heat dissipation path. The design is sufficiently slim, to position it in a fairly compact permanent magnet. The calculated filling factor was found to be η=0.6. The diamonds used in this Example are [1 1 1] oriented, so that the static magnetic field, which is directed along the cavity cylindrical axis is also directed along this NV axis for optimal energy levels pumping efficiency. The NV concentration was measured to be about 20 ppm.

### Results and Discussion

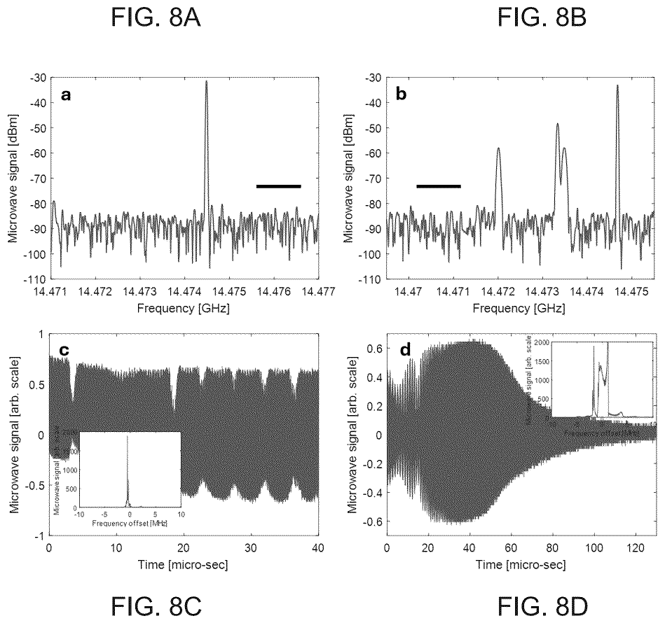

The maser oscillator was initially tested using an electromagnet as the source of the static magnetic field, which exhibited field fluctuations. The emitted microwave signal was monitored in the frequency domain using a spectrum analyzer, with all measurements conducted at a temperature of 180K. FIG. 8A presents a typical MW signal captured in one of the spectrum analyzer scans. This scan demonstrates an unprecedentedly high output power of nearly 1 μW, along with fairly good spectral quality. More chaotic patterns were observed in other scans, sometimes featuring multiple spectral lines, as shown in FIG. 8B. Two possible causes for this instability are identified: (i) Fluctuations in the electromagnetic field, which can vary by a few tenths of a Gauss (as measured by a Gaussmeter with a time resolution of about 10 ms), leading to spectral shifts exceeding 1 MHz; and (ii) the native spectral linewidth of the sample is relatively broad (6.4 MHz). This broad linewidth, combined with potential nonlinear behavior and mode competition under such conditions, can contribute to spectral fluctuations.

To better understand this behavior, the spectral variations in the time domain were analyzed by feeding the maser MW signal into the pulsed ESR spectrometer, recording it as a standard ESR signal with down-conversion to 50 MHz. FIG. 8C shows a representative time-domain trace for periods with relatively stable spectral output, and FIG. 8D displays a typical signal during periods of faster frequency fluctuations.

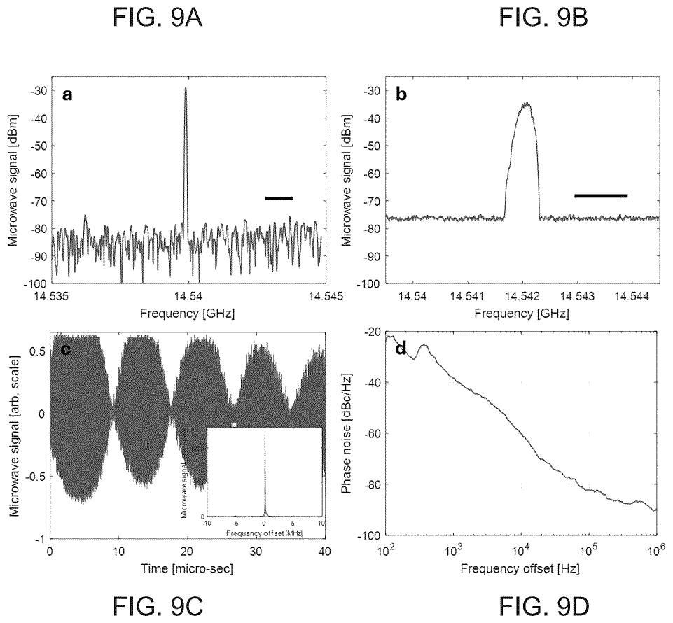

The maser resonator was then placed inside a superconducting magnet operated in persistent mode, which significantly reduced static magnetic field fluctuations compared to the previously used electromagnet. This resulted in improved spectral stability. FIG. 9A presents a representative spectrum of the maser signal acquired under these conditions using a spectrum analyzer. All measurements were conducted at 180 K. In comparison to measurements taken with the electromagnet, good spectral purity was observed in most scans, with output power slightly exceeding −30 dBm (about 1 μW). The maser signal continued to exhibit frequency jitter, as evident from FIG. 9B. This can be attributed to the aforementioned nonlinear phenomenon. FIG. 9B shows several scans acquired using the analyzer's “max hold” mode, which records the maximum signal detected at each frequency across many scans. The corresponding time-domain signal (FIG. 9C) further illustrates this frequency instability.

When the maser was operated at relatively high optical excitation power (about 1.2 W for each LED), a frequency jitter approaching 1 MHz (FIG. 9B) prevented the spectrum analyzer from locking onto the maser frequency, hindering accurate phase noise measurements. To mitigate this issue, the maser was operated closer to its threshold, using a reduced optical excitation power of about 440 mW. Under these conditions, the frequency jitter decreased substantially to about 10 kHz, as oscillations could occur only near the peak of the NV ensemble's spectral line. This also reduced the maser output power to approximately −70 dBm, making direct phase noise measurements challenging due to thermal noise interference. This limitation was overcome by pre-amplifying the maser signal using a very low-noise amplifier (Model LNF-LNC6_20A, Low Noise Factory, Sweden) before going into the spectrum analyzer. The resulting phase noise spectrum of the free-running maser, operated at minimal optical excitation power and with LNA amplification, is shown in FIG. 9D.

The results show, for the first time, that a free-running solid-state maser, based on diamond NVs, can reach output power levels of more than 1 μW at very moderate cryogenic temperatures. Such power levels are well above what was achieved in conventional solid-state masers of similar size at all temperatures. At this power level of more than −30 dBm and a temperature of 180 K, the ultimate thermally limited phase noise level is approximately −150 dBc. However, the measured phase noise was far from these values. This is attributed to the relatively broad linewidth of the NV transition and, mainly, to the lack of any high-Q resonator connected via a feedback loop for locking and stabilizing the maser frequency. Such a high-Q resonator is typical and advantageous for producing a low-phase-noise microwave source. Quantitatively, one can analyze this situation using Leeson's equation, which provides an estimation of the expected phase noise of a system with an amplifier (the maser, in this case) coupled to a high-Q factor external resonator, when the amplifier noise characteristics and other relevant parameters are known:

$$L ( {f}_{m} ) = 10 log [ \frac{{k}_{B} {T}_{sys}}{2 {P}_{in}} ( 1 + {( \frac{{f}_{0}}{2 {Q}_{ext} {f}_{m}} )}^{2} ) ( 1 + \frac{{f}_{c}}{{f}_{m}} ) ] ,$$

where, Pᵢₙ is the input power before the maser amplifier, considered in this Example as Pᵢₙ=0.1W, to avoid maser output saturation and still provides a gain of at least 10 dB. The term f₀ is the operating frequency of the oscillator, [symbol] is the loaded quality factor of the oscillator, which can be approximated by the loaded Q factor of the external resonator. The term fₘ denotes the offset frequency from the carrier, and f_{c} is the flicker corner frequency representing the 1/f noise contribution. Note that in the standard form of Leeson's equation, one typically finds the factor Fk_{B}T rather than simply k_{B}T_{sys}, where F is the noise figure of the amplifier and T is the ambient temperature. In the case of a maser, its equivalent noise temperature, T_{sys}, can be much lower than the ambient temperature. This is similar to the case of cryogenic amplifiers with noise temperatures significantly lower than the ambient temperature. In such cases, the term F·T₀ (F being the noise figure and T₀ the ambient temperature) loses its physical meaning unless F<1, which is not a proper way to interpret the situation. Instead, the ability to achieve T_{sys}<<T₀ is where the maser reveals its potential as a low-phase-noise microwave source, provided its saturation power is sufficiently high.

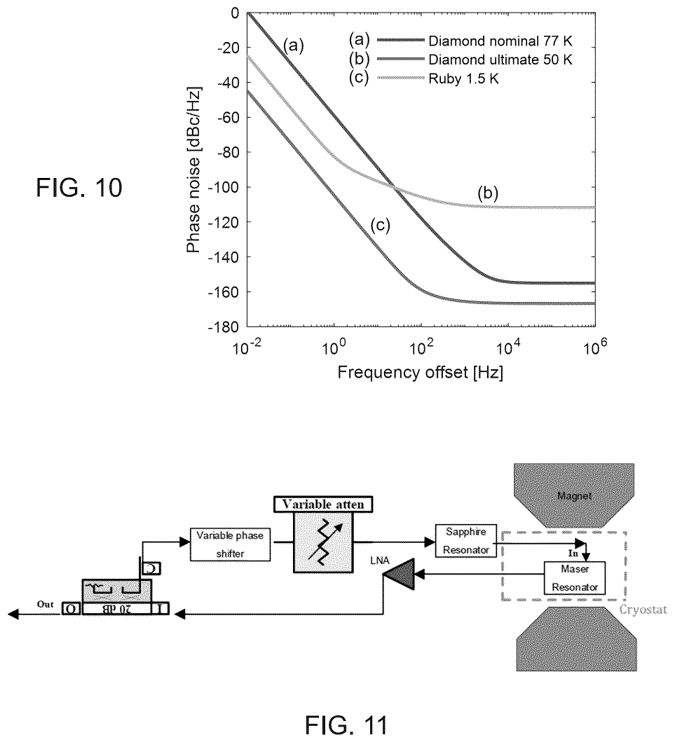

FIG. 10 presents preliminary estimates of phase noise, based on the above form of Leeson's equation, demonstrating the ability of the maser of the present embodiments to be used in low-phase-noise microwave sources. These estimates consider operation at about 77 K and 50 K, temperatures that are still achievable using He-free, rugged Stirling cryogenic coolers. The “Nominal” values referred to in the brief description of FIG. 10 correspond to the performance achieved in this example, assuming coupling to a high-Q sapphire resonator with Qₑₓₜ=2×10⁶ via a 20 dB directional coupler (FIG. 11), which is feasible at 77 K. The system noise temperature T_{sys} is estimated in FIG. 10 at 4.5 K, using a standard expression for the amplifier noise temperature of a single-port maser amplifier. This estimate assumes an ambient temperature T₀=77 K, a spin temperature approaching the quantum limit Tₘ≈0.65 K, and coupling factor ε=0.05, implying that the maser resonator quality factor (about 2000 in this example) is approximately 20 times larger than [symbol] , see EQ. 1 in Example 1. The value of Qₘ˜100 is roughly estimated in this case based on the ratio between the minimal LED power required to achieve the maser threshold (about 60 mW in each LED) to the maximum employed LED power (1.2 W for each LED, in this case). The “Ultimate” values, referred to in the brief description of FIG. 10, represent a performance assuming a tenfold increase in saturation power and, advantageously, coupling the amplifier to an ultra-high-Q sapphire resonator with [symbol] ˜10⁸, operating at 50 K. The expected performance of diamond-based masers is compared with that of ruby-based masers operating at about 2.6 GHz, in combination with ultra-high-Q sapphire resonators housed in superconducting shields at about 1.5 K.

### CONCLUSION

This Example demonstrated a diamond-based maser that produces relatively high output power. Such performance is suitable for use as sources of ultra-low phase noise microwave signals. The advantage of the diamond-based maser described in this Example over ruby-based masers lies in the ability of the diamond-based maser to operate at significantly higher ambient temperatures, eliminating the need for liquid helium cooling, while still maintaining comparable and even superior overall equivalent system noise temperatures. The diamond-based maser described herein can sustain higher output power within compact form factors, which is advantageous as it allows achieving low phase noise performance at relatively large frequency offsets from the carrier.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A microwave resonator for a microwave source system, comprising a metallic structure formed with a cylindrical cavity defining a symmetry axis and having a top end and a bottom end, a pair of cylindrical diamonds positioned in said cavity at said top and bottom ends, and a layered dielectric structure between said diamonds;
wherein a microwave magnetic field is generated perpendicularly to said symmetry axis in response to a static magnetic field and an excitation optical field directed parallel to said symmetry axis.

2. The microwave resonator according to claim 1, wherein said layered dielectric structure comprises a core layer made of a first dielectric between two layers made of a second dielectric.

3. The microwave resonator according to claim 2, wherein said first dielectric is a single crystal.

4. The microwave resonator according to claim 2, wherein said second dielectric is a single crystal.

5. The microwave resonator according to claim 2, wherein said first dielectric comprises Al₂O₃.

6. The microwave resonator according to claim 2, wherein said second dielectric is a perovskite.

7. The microwave resonator according to claim 6, wherein said second dielectric comprises LaAlO₃.

8. The microwave resonator according to claim 1, comprising an elongated dielectric insert, movable along a radial direction perpendicularly to said symmetry axis.

9. The microwave resonator according to claim 2, comprising an elongated dielectric insert, movable along a radial direction perpendicularly to said symmetry axis.

10. The microwave resonator according to claim 9, wherein said insert is made of said first dielectric.

11. The microwave resonator according to claim 8, wherein said insert is shaped as a rod.

12. The microwave resonator according to claim 1, wherein each of said diamonds has a have [1 1 1] orientation.

13. The microwave resonator according to claim 1, wherein each of said diamonds has paramagnetic defects.

14. The microwave resonator according to claim 13, wherein said paramagnetic defects comprise nitrogen impurities.

15. The microwave resonator according to claim 14, wherein a concentration of said nitrogen impurities is from about 3 ppm to about 20 ppm.

16. The microwave resonator according to claim 1, wherein dimensions of the cavity and said diamonds are is selected such that a filling factor associated with said microwave magnetic field is at least 0.7.

17. A microwave source system comprising the microwave resonator according to claim 1.

18. The system according to claim 17, comprising a magnet having magnetic poles generating said static magnetic field, wherein a distance between said poles and said diamonds is less than 25 mm.

19. The system according to claim 17, comprising light sources outside said cavity, wherein a distance between said light sources and said diamonds is less than 5 mm.

20. The system according to claim 17, serving as a component in an appliance system selected from the group consisting of a microwave interferometry system, a navigation system, a communication system, a radar system, an imaging system, an ablation system, and a microwave radiometer.
